(19) United States
(12) Patent Application Publication
(10) Pub. No.: US 2026/0040593 A1
(43) Pub. Date: Feb. 5, 2026

(54) CAPACITOR

(71) Applicant: Panasonic Intellectual Property Management Co., Ltd., Osaka (JP)

(72) Inventors: Yosuke HAGIHARA, Osaka (JP); Kazushi YOSHIDA, Osaka (JP); Tomohiro FUJITA, Osaka (JP)

(73) Assignee: Panasonic Intellectual Property Management Co., Ltd., Osaka (JP)

(21) Appl. No.: 19/115,913

(22) PCT Filed: Aug. 23, 2023
(86) PCT No.: PCT/JP2023/030275

§ 371 Date: Mar. 27, 2025

(30) Foreign Application Priority Data
Sep. 29, 2022 (JP) 2022-156722

(51) Int. Cl. H10D 1/68; H10D 1/00

(52) U.S. Cl. CPC H10D 1/716; H10D 1/043

(57) ABSTRACT

A capacitor includes a silicon substrate, a dielectric layer, and a conductor layer. The silicon substrate has a doped layer. The doped layer includes a first doped layer disposed along a second region of a first principal surface of the silicon substrate, a second doped layer disposed at a bottom part of the porous part of the silicon substrate, and a third doped layer disposed at a side part of the porous part of the silicon substrate. The doped layer includes a first portion connecting the first doped layer to the third doped layer and having a first curved part concavely curved in a cross-sectional view. The doped layer includes a second portion connecting the second doped layer to the third doped layer and having a second curved part convexly curved in the cross-sectional view.

### TECHNICAL FIELD

The present disclosure relates to capacitors and more specifically relates to a capacitor including a silicon substrate.

### BACKGROUND ART

Patent Literature 1 discloses a capacitor including a silicon substrate, a conductor layer, and a dielectric layer. The silicon substrate has a first principal surface and a second principal surface. The first principal surface of the silicon substrate includes a capacity exhibiting region and non-capacity exhibiting region. The silicon substrate includes a porous part formed in a thickness direction in the capacity exhibiting region of the first principal surface. The porous part has a plurality of micropores.

For capacitors, an improvement in electrical characteristics may be desired.

### Citation List

### Patent Literature

Patent Literature 1: WO 2020/184517 A1

### Summary of Invention

It is an object of the present disclosure to provide a capacitor having improved electrical characteristics.

A capacitor of an aspect of the present disclosure includes a silicon substrate, a dielectric layer, and a conductor layer. The silicon substrate has a first principal surface including a first region and a second region surrounding the first region, a second principal surface, and a porous part formed in the first region and having a plurality of micropores along a thickness direction defined with respect to the silicon substrate. The dielectric layer is disposed over a surface of the porous part and the second region of the silicon substrate. The conductor layer is disposed on the dielectric layer. An interval between adjacent micropores of the plurality of micropores is ununiform in the thickness direction defined with respect to the silicon substrate. The conductor layer overlaps the first region and the second region in plan view in the thickness direction defined with respect to the silicon substrate. The silicon substrate has a doped layer containing a p-type dopant or an n-type dopant. The doped layer includes a first doped layer, a second doped layer, and a third doped layer. The first doped layer is disposed along the second region of the silicon substrate. The second doped layer is disposed at a bottom part of the porous part of the silicon substrate. The third doped layer is disposed at a side part of the porous part of the silicon substrate. The doped layer has a first portion connecting the first doped layer to the third doped layer. The first portion has a first curved part concavely curved in a cross-sectional view in a second direction orthogonal to a first direction which is the thickness direction. The doped layer includes a second portion connecting the second doped layer to the third doped layer. The second portion has a second curved part convexly curved in the cross-sectional view.

A capacitor of another aspect of the present disclosure includes a silicon substrate, a dielectric layer, and a conductor layer. The silicon substrate has a first principal surface including a first region and a second region surrounding the first region, a second principal surface, and a porous part formed in the first region and having a plurality of micropores along a thickness direction defined with respect to the silicon substrate. The dielectric layer is disposed over a surface of the porous part and the second region of the silicon substrate. The conductor layer is disposed on the dielectric layer. An interval between adjacent micropores of the plurality of micropores is ununiform in the thickness direction defined with respect to the silicon substrate. The conductor layer overlaps the first region and the second region in plan view in the thickness direction defined with respect to the silicon substrate. The silicon substrate has a doped layer containing a p-type dopant or an n-type dopant. The doped layer includes a first doped layer, a second doped layer, and a third doped layer. The first doped layer is disposed along the second region of the silicon substrate. The second doped layer is disposed at a bottom part of the porous part of the silicon substrate. The third doped layer is disposed at a side part of the porous part of the silicon substrate. In the doped layer, the first doped layer is connected to the third doped layer, and a smaller angle of two angles formed between the first doped layer and the third doped layer is an obtuse angle in a cross-sectional view in a second direction orthogonal to a first direction which is the thickness direction. In the doped layer, the second doped layer is connected to the third doped layer, and a smaller angle of two angles formed between the second doped layer and the third doped layer is an obtuse angle in the cross-sectional view.

### BRIEF DESCRIPTION OF DRAWINGS

FIG. 1 is a schematic cross-sectional view of a capacitor according to a first embodiment;

FIG. 2 is an enlarged view of a main part in a cross section of the capacitor;

FIG. 3 is a plan view of the capacitor;

FIGS. 4A and 4B are cross-sectional views for illustrating steps in a method of manufacturing the capacitor;

FIGS. 5A and 5B are cross-sectional views for illustrating steps in the method of manufacturing the capacitor;

FIG. 6A is a surface SEM image of a silicon substrate in which a porous part has been formed in the method of manufacturing the capacitor;

FIG. 6B is a cross-sectional SEM image of the silicon substrate in which the porous part has been formed in the method of manufacturing the capacitor;

FIGS. 7A and 7B are cross-sectional views for illustrating steps in the method of manufacturing the capacitor;

FIG. 8 is a schematic cross-sectional view of a capacitor according to a second embodiment; and

FIG. 9 is an enlarged view of a main part in a cross section of the capacitor of the second embodiment.

### DESCRIPTION OF EMBODIMENTS

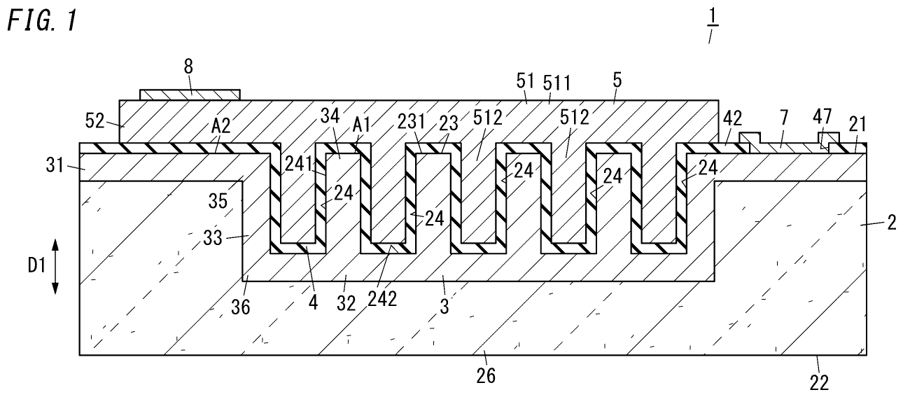

FIGS. 1 to 9 described in first and second embodiments and the like below are schematic views, and ratio of sizes and the ratio of thicknesses of components in the drawings do not necessarily reflect actual dimensional ratios.

### First Embodiment

### (1.1) Overview

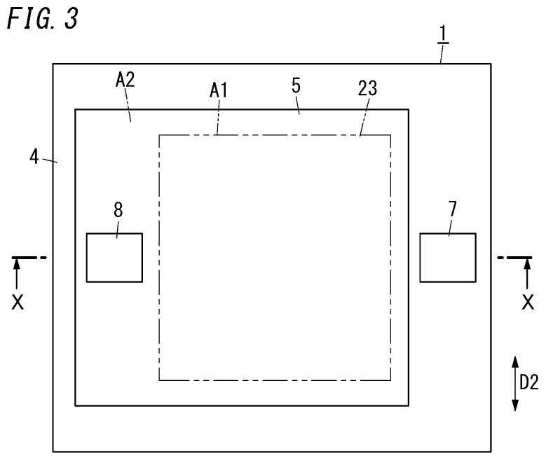

A capacitor 1 according to the first embodiment will be described below with reference to FIGS. 1 to 3. Note that FIG. 1 is a cross-sectional view taken along line X-X of FIG. 3.

The capacitor 1 includes a silicon substrate 2, a dielectric layer 4, and a conductor layer 5. The silicon substrate 2 has a first principal surface 21 and a second principal surface 22. The silicon substrate 2 has a porous part 23 having a plurality of micropores 24 formed in the first principal surface 21. Moreover, the silicon substrate 2 has a doped layer 3 containing a p-type dopant (e.g., boron or indium). The doped layer 3 is disposed along a surface 231 of the porous part 23. The dielectric layer 4 has a shape conforming to the shape of the surface 231 of the porous part 23 and is disposed on the doped layer 3. The conductor layer 5 is disposed on the dielectric layer 4.

In the capacitor 1, the doped layer 3 constitutes a first electrode of the capacitor 1, and the conductor layer 5 constitutes a second electrode of the capacitor 1. Thus, in the capacitor 1, the dielectric layer 4 is located between the first electrode and the second electrode.

Moreover, the capacitor 1 further includes a first external connection electrode 7 and a second external connection electrode 8. The first external connection electrode 7 is connected to the doped layer 3. The second external connection electrode 8 is connected to the conductor layer 5.

### (1.2) Components of Capacitor

Components of the capacitor 1 will be described in further detail below.

### (1.2.1) Silicon Substrate

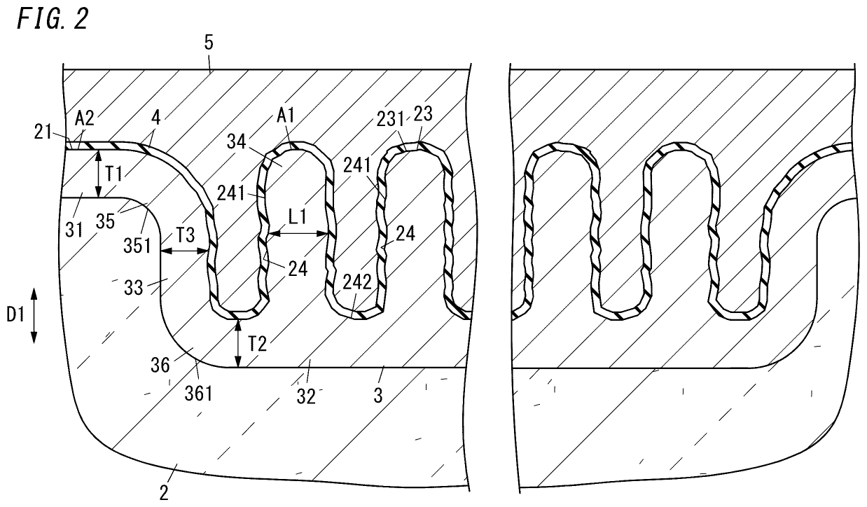

As shown in FIGS. 1 and 2, the silicon substrate 2 has a first principal surface 21 and a second principal surface 22 opposite the first principal surface 21. In plan view in a thickness direction D1 defined with respect to the silicon substrate 2, the silicon substrate 2 has an outer edge having a rectangular shape. The silicon substrate 2 has a thickness of, for example, greater than or equal to 300 μm and less than or equal to 1 mm.

The silicon substrate 2 includes, on the first principal surface 21, a first region A1 including the porous part 23 formed therein and a second region A2 surrounding the first region A1 (see FIGS. 1 and 3). In plan view in the thickness direction D1 defined with respect to the silicon substrate 2, the first region A1 is a rectangular region and is surrounded by the second region A2. The first region A1 is not limited to the rectangular region when viewed in the thickness direction D1 defined with respect to the silicon substrate 2, but the first region A1 may be, for example, a circular region, a polygonal region other than the rectangular shape, or a region in the shape of a polygon other than convex polygons.

The porous part 23 has a plurality of micropores 24 along the thickness direction D1 defined with respect to the silicon substrate 2. The plurality of micropores 24 are disposed in the first principal surface 21 of the silicon substrate 2. The plurality of micropores 24 are each a pore having a greater depth from the first principal surface 21 of the silicon substrate 2 in the thickness direction D1 defined with respect to the silicon substrate 2 than an opening width thereof at the first principal surface 21 of the silicon substrate 2. The plurality of micropores 24 are disposed in the thickness direction of the silicon substrate 2 from the first principal surface 21 of the silicon substrate 2 and do not reach the second principal surface 22. In other words, the plurality of micropores 24 do not penetrate through the silicon substrate 2 in the thickness direction DI defined with respect to the silicon substrate 2. That is, the plurality of micropores 24 are apart from the second principal surface 22 of the silicon substrate 2. The plurality of micropores 24 each have an opening width of, for example, greater than or equal to 0.1 μm and less than or equal to 10 μm at the first principal surface 21 of the silicon substrate 2. Moreover, the plurality of micropores 24 each have a depth of smaller than the thickness of the silicon substrate 2. The depths of the plurality of micropores 24 in the thickness direction DI defined with respect to the silicon substrate 2 are, for example, greater than or equal to 20 μm and less than or equal to 300 μm, more preferably greater than or equal to 30 μm and less than or equal to 100 μm. Note that an upper limit value of the depths of the plurality of micropores 24 may accordingly be determined based on, for example, the opening widths of the plurality of micropores 24 and a formation method of each of the doped layer 3, the dielectric layer 4, and the conductor layer 5. The opening width and the depth of each micropore 24 in the porous part 23 of the silicon substrate 2 are values determined from, for example, a cross-sectional scanning electron microscope (SEM) image of the capacitor 1.

The surface 231 of the porous part 23 includes: an inner side surface 241 and an inner bottom surface 242 of each of the plurality of micropores 24 formed in the first principal surface 21 of the silicon substrate 2; and part of the first principal surface 21 of the silicon substrate 2.

The greater the depths of the plurality of micropores 24 in the porous part 23 the capacitor 1 are, the larger the surface area of the surface 231 of the porous part 23 and thus the greater the capacitance of the capacitor 1. Moreover, the larger the number of micropores 24 in the porous part 23 of the capacitor 1 is, the larger the surface area of the surface 231 of the porous part 23 and thus the greater the capacitance of the capacitor 1.

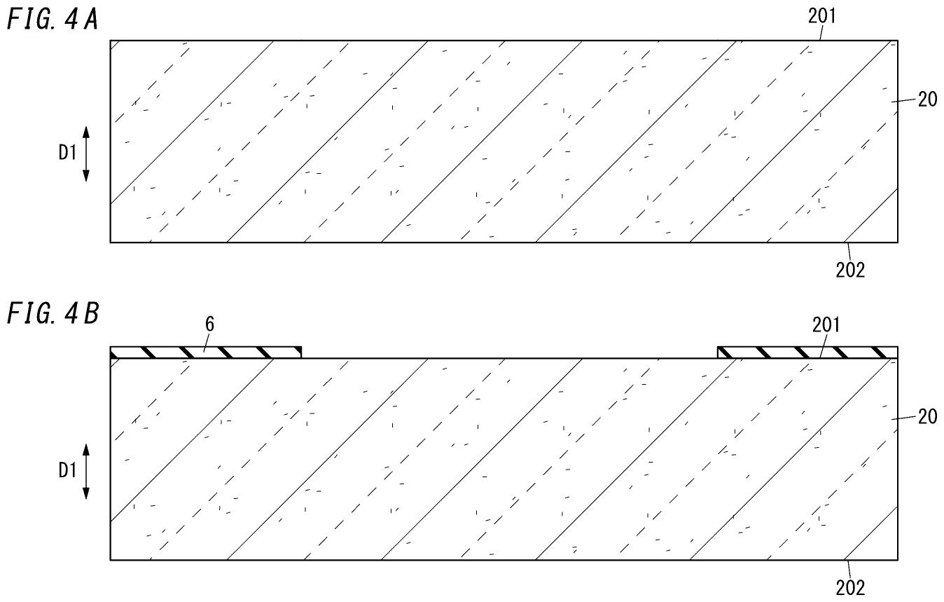

The silicon substrate 2 having the porous part 23 and the doped layer 3 is formed by anodizing, for example, a p-type silicon wafer 20 (see FIG. 4A), and then, performing a dopant diffusion step. That is, the plurality of micropores 24 in the porous part 23 are formed by anodizing a region which is part of the p-type silicon wafer 20 and which corresponds to the first region A1 of the silicon substrate 2.

In the capacitor 1, an interval L1 between two adjacent micropores 24 of the plurality of micropores 24 is ununiform in the thickness direction DI defined with respect to the silicon substrate 2 as shown in FIG. 2. In the capacitor 1, the surface area of the surface 231 of the porous part 23 is large as compared with the case where the interval L1 between two adjacent micropores 24 of the plurality of micropores 24 is uniform in the thickness direction DI defined with respect to the silicon substrate 2. Note that the interval L1 between two adjacent micropores 24 of the plurality of micropores 24 is uniform in the thickness direction D1 defined with respect to the silicon substrate 2 when the plurality of micropores 24 are formed by, for example, dry etching. Moreover, in the capacitor 1, the plurality of micropores 24 each have an ununiform opening width in the thickness direction D1 defined with respect to the silicon substrate 2.

In a cross-sectional view in a second direction D2 (see FIG. 3) orthogonal to the thickness direction D1 (hereinafter also referred to as a first direction D1) defined with respect to the silicon substrate 2, the inner side surface 241 of one micropore 24 of the two adjacent micropores 24 and the inner side surface 241 of the other micropore 24 of the two adjacent micropores 24 are both not in the form of a straight line but in the form of a line with concave and convex parts. The difference in height between a trough and a crest respectively of the concave and convex parts is smaller than the opening width of the micropore 24. The difference in height between the trough and the crest respectively of the concave and convex parts is a value determined from, for example, a cross-sectional scanning electron microscope (SEM) image of the capacitor 1. The difference in height between the trough and the crest respectively of the concave and convex parts may be changed depending on: the impurity concentration of the p-type silicon wafer 20 (see FIG. 4A) from which the silicon substrate 2 is to be formed; and conditions of anodization.

The inner bottom surface 242 of each of the plurality of micropores 24 in the porous part 23 has a concave shape (see FIG. 2). The inner bottom surface 242 of each of the plurality of micropores 24 has a curvature radius greater than or equal to 1.25 nm.

The capacitor 1 has a body region 26 located between the doped layer 3 and the second principal surface 22 of the silicon substrate 2 and having an impurity concentration equal to the impurity concentration of the p-type silicon wafer 20. Moreover, the body region 26 of the silicon substrate 2 has a carrier concentration of equal to the carrier concentration of the p-type silicon wafer 20 (see FIG. 4A). When the silicon substrate 2 is formed from the p-type silicon wafer 20, the body region 26 of the silicon substrate 2 includes, for example, boron (B) as a dopant, but this should not be construed as limiting. The body region 26 may contain indium (In) as a dopant. The impurity concentration of the body region 26 of the silicon substrate 2 is, for example, greater than or equal to 1×10¹³ cm⁻³ and less than or equal to 1×10¹⁷ cm⁻³, more preferably greater than or equal to 5×10¹³ cm⁻³ and less than or equal to 5×10¹⁶ cm⁻³. The impurity concentration of the body region 26 of the silicon substrate 2 is a value determined by, for example, secondary ion mass spectroscopy (SIMS) analysis.

The doped layer 3 which the silicon substrate 2 has is a diffusion layer. The conductivity type of the doped layer 3 is the same as the conductivity type of the body region 26 of the silicon substrate 2. Moreover, the impurity concentration of the doped layer 3 is higher than the impurity concentration of the body region 26 of the silicon substrate 2. Thus, when the conductivity type of the body region 26 of the silicon substrate 2 is p-type, the doped layer 3 is a p-type silicon region (a p⁺ silicon region) having a higher concentration than the body region 26 of the silicon substrate 2. The dopant type of the doped layer 3 is, for example, the same as the dopant type of the body region 26 of the silicon substrate 2. More specifically, when the dopant of the body region 26 is boron, the dopant of the doped layer 3 is boron. The impurity concentration of the doped layer 3 is greater than or equal to 1×10¹⁸ cm⁻³ and less than or equal to 1×10²¹ cm⁻³, more preferably greater than or equal to 5×10¹⁸ cm⁻³ and less than or equal to 1×10²⁰ cm⁻³. The impurity concentration of the doped layer 3 is a value obtained by, for example, SIMS analysis.

Moreover, the carrier concentration of the doped layer 3 is higher than the carrier concentration of the body region 26. The carrier concentration of the doped layer 3 and the carrier concentration of the body region 26 are values determined by, for example, carrier concentration distribution observation by using a scanning microwave impedance microscope (sMIM).

For discussion about the relative magnitude relationship between the carrier concentration of the doped layer 3 and the carrier concentration of the body region 26, the carrier concentrations are not limited to the values determined by the carrier concentration distribution observation by using the sMIM. The carrier concentration of the doped layer 3 and the carrier concentration of the body region 26 may be values determined by, for example, carrier concentration distribution observation by scanning capacitance microscopy (SCM). The carrier concentration of the doped layer 3 and the carrier concentration of the body region 26 may be values determined by, for example, carrier concentration distribution observation by scanning nonlinear dielectric microscopy (SNDM).

The thickness of the doped layer 3 is greater than or equal to 10 nm and less than or equal to 10000 nm, more preferably greater than or equal to 50 nm and less than or equal to 5000 nm. The thickness of the doped layer 3 is a value determined by, for example, observing the cross section of the capacitor 1 by using a scanning microwave impedance microscope (sMIM). The thickness of the doped layer 3 is a thickness of the doped layer 3 in a normal direction to an arbitrary point on an inner surface (the inner side surface 241 and the inner bottom surface 242) of the micropore 24.

The doped layer 3 which the silicon substrate 2 has is disposed over the first region A1 and the second region A2 of the first principal surface 21 of the silicon substrate 2. The doped layer 3 is disposed along the surface 231 of the porous part 23 in the first region A1 and is disposed along the second region A2 in the second region A2.

The doped layer 3 includes a first doped layer 31, a second doped layer 32, and a third doped layer 33.

The first doped layer 31 is disposed along the second region A2 of the silicon substrate 2. The second doped layer 32 is disposed at a bottom part of the porous part 23 of the silicon substrate 2. The third doped layer 33 is disposed at a side part of the porous part 23 of the silicon substrate 2. The thickness T1 of the first doped layer 31, the thickness T2 of the second doped layer 32, and the thickness T3 of the third doped layer 33 are equal to one another.

The doped layer 3 has a first portion 35 connecting the first doped layer 31 to the third doped layer 33. The first portion 35 has a first curved part 351 concavely curved (arc-shaped) in a cross-sectional view in the second direction D2. The doped layer 3 has a second portion 36 connecting the second doped layer 32 to the third doped layer 33. The second portion 36 has a second curved part 361 convexly curved (arc-shaped) in the cross-sectional view.

In the doped layer 3, the first curved part 351 has a curvature radius greater than or equal to 10 nm and less than or equal to 10 μm. Moreover, the second curved part 361 has a curvature radius greater than or equal to 10 nm and less than or equal to 10 μm.

Moreover, the doped layer 3 further includes a fourth doped layer 34. The fourth doped layer 34 is disposed at a portion between two adjacent micropores 24 of the plurality of micropores 24 in the porous part 23 of the silicon substrate 2. The portion between two adjacent micropores 24 preferably has a width less than or equal to two times the thickness T3 of the third doped layer 33.

### (1.2.2) Dielectric Layer

The dielectric layer 4 is disposed on the doped layer 3 and has a shape conforming to the shape of the surface 231 of the porous part 23 in the first region A1 and the shape of the second region A2 of the first principal surface 21 of the silicon substrate 2. The dielectric layer 4 has: a portion between the doped layer 3 and the conductor layer 5 in the thickness direction D1 defined with respect to the silicon substrate 2; and a portion between the doped layer 3 and the conductor layer 5 in the plurality of micropores 24 in the porous part 23.

The dielectric layer 4 has a thickness of, for example, greater than or equal to 10 nm and less than or equal to 500 nm. An upper limit of the thickness of the dielectric layer 4 is limited by, for example, the opening widths of the micropores 24 in the porous part 23 in one direction along the first principal surface 21 of the silicon substrate 2 and the thickness in the one direction of the conductor layer 5 in the micropores 24 in the porous part 23.

The dielectric layer 4 has a multilayer film structure including a plurality of dielectric films stacked one on top of another, but this should not be construed as limiting. The dielectric layer 4 may include a single dielectric film. When the dielectric layer 4 has the multilayer film structure, the dielectric layer 4 includes, for example: a first dielectric film (e.g., a first silicon oxide film) on the doped layer 3; a second dielectric film (e.g., a silicon nitride film) on the first dielectric film; and a third dielectric film (e.g., a second silicon oxide film) on the second dielectric film. A material for the first silicon oxide film and the second silicon oxide film is, for example, silicon dioxide (SiO₂). The composition of each of the first silicon oxide film and the second silicon oxide film does not necessarily have to be SiO₂ in a strict sense. Moreover, the composition of the first silicon oxide film may be different from the composition of the second silicon oxide film. When the dielectric layer 4 includes a single dielectric film, a material for the dielectric film is, for example, silicon oxide. The material for the dielectric film is not limited to the silicon oxide but may be, for example, titanium oxide, zirconium oxide, hafnium oxide, vanadium oxide, tungsten oxide, niobium oxide, tantalum oxide, or aluminum oxide.

### (1.2.3) Conductor Layer

The conductor layer 5 is disposed on the dielectric layer 4. The conductor layer 5 overlaps the first region A1 and the second region A2 of the first principal surface 21 of the silicon substrate 2 in plan view in the thickness direction D1 defined with respect to the silicon substrate 2. Therefore, the conductor layer 5 overlaps the first doped layer 31, the second doped layer 32, and the third doped layer 33 of the doped layer 3 in plan view in the thickness direction D1 defined with respect to the silicon substrate 2.

The conductor layer 5 is, for example, a conductive polycrystalline silicon layer. The impurity concentration of the conductive polycrystalline silicon layer is, for example, greater than or equal to 1×10¹⁸ cm⁻³ and less than or equal to 1×10²¹ cm⁻³, more preferably greater than or equal to 5×10¹⁸ cm⁻³ and less than or equal to 1×10²⁰ cm⁻³. The dopant of the conductive polycrystalline silicon layer includes one selected from the group consisting of, for example, boron, indium, phosphorus, arsenic, and antimony. The conductor layer 5 is not limited to the conductive polycrystalline silicon layer but may be, for example, a metal electrode layer. A material for the metal electrode layer includes at least one selected from the group consisting of, for example, ruthenium (Ru), titanium (Ti), tantalum (Ta), tungsten (W), and aluminum (Al). More specifically, the material for the metal electrode layer is, for example, ruthenium, titanium, tantalum, tungsten, aluminum, or an alloy including one of these metals as a main component.

The conductor layer 5 has a first portion 51 overlapping the first region A1 and a second portion 52 overlapping the second region A2 in the thickness direction D1 defined with respect to the silicon substrate 2. The first portion 51 of the conductor layer 5 includes: a plurality of columnar portions 512 located in the plurality of micropores 24 in the porous part 23 of the silicon substrate 2; and a portion 511 to which upper ends of the plurality of columnar portions 512 are connected.

### (1.2.4) First External Connection Electrode and Second External Connection Electrode

The first external connection electrode 7 is connected to the doped layer 3 of the silicon substrate 2. More specifically, the first external connection electrode 7 is connected to the first principal surface 21 of the silicon substrate 2, and to the doped layer 3, through a contact hole 47 formed in a portion 42 of the dielectric layer 4. The portion 42 is disposed on the second region A2 of the first principal surface 21 of the silicon substrate 2. In the capacitor 1, the first external connection electrode 7 is electrically connected to the doped layer 3 of the silicon substrate 2. Saying that “the first external connection electrode 7 is electrically connected to the doped layer 3 of the silicon substrate 2” means that the first external connection electrode 7 is in ohmic contact with (the first doped layer 31 of) the doped layer 3 of the silicon substrate 2.

In plan view in the thickness direction D1 defined with respect to the silicon substrate 2, the first external connection electrode 7 has an outer edge having, for example, a quadrangular shape (see FIG. 3), but this should not be construed as limiting. The outer edge may have, for example, a circular shape. The first external connection electrode 7 is disposed over part of the first principal surface 21 of the silicon substrate 2, an inner peripheral surface of the contact hole 47 in the insulating layer 6, and part of the first doped layer 31. The first external connection electrode 7 overlaps the second region A2 but does not overlap the first region A1 of the first principal surface 21 of the silicon substrate 2 in plan view in the thickness direction D1 defined with respect to the silicon substrate 2.

The second external connection electrode 8 is connected to the conductor layer 5. In the capacitor 1, the second external connection electrode 8 is electrically connected to the conductor layer 5. Saying that “the second external connection electrode 8 is electrically connected to the conductor layer 5” means that the second external connection electrode 8 is in ohmic contact with the conductor layer 5. The second external connection electrode 8 overlaps the second region A2 but does not overlap the first region A1 of the first principal surface 21 of the silicon substrate 2 in plan view in the thickness direction D1 defined with respect to the silicon substrate 2.

A material for the first external connection electrode 7 and the second external connection electrode 8 includes, for example, but is not limited to, aluminum and may include, for example, gold, platinum, and ruthenium. The material for the second external connection electrode 8 is the same as the material for the first external connection electrode 7, but this should not be construed as limiting. The material for the second external connection electrode 8 may be a material different from the material for the first external connection electrode 7.

The thickness of each of the first external connection electrode 7 and the second external connection electrode 8 is, for example, greater than or equal to 1 μm and less than or equal to 3 μm. The thickness of the second external connection electrode 8 is equal to the thickness of the first external connection electrode 7, but this should not be construed as limiting. The thickness of the second external connection electrode 8 may be different from the thickness of the first external connection electrode 7.

### (2) Method of Manufacturing Capacitor

A method of manufacturing the capacitor 1 includes, for example, a first step, a second step, a third step, a fourth step, a fifth step, a sixth step, a seventh step, and an eighth step. The method of manufacturing the capacitor 1 will be described below with reference to FIGS. 4A, 4B, 5A, 5B, 6A, 6B, 7A, and 7B.

The first step includes preparing the p-type silicon wafer 20 (see FIG. 4A) from which the silicon substrate 2 is to be formed. The p-type silicon wafer 20 has a first principal surface 201 and a second principal surface 202 opposite the first principal surface 201. The first principal surface 201 of the p-type silicon wafer 20 is, for example, the (100) plane, but this should not be construed as limiting. The first principal surface 201 may be, for example, the (110) plane or the (111) plane. Moreover, the first principal surface 201 of the p-type silicon wafer 20 may be, for example, a crystal surface whose off angle from the (100) plane is greater than 0° and less than or equal to 5°. In this embodiment, the “off angle” is an inclined angle of the first principal surface 201 with respect to the (100) plane. Thus, when the off angle is 0°, the first principal surface 201 is the (100) plane.

The second step includes forming the insulating layer 6 (see FIG. 4B) having a prescribed pattern on the first principal surface 201 of the p-type silicon wafer 20. To form the insulating layer 6 having the prescribed pattern, for example, first processing and second processing are performed. The first processing includes: forming a silicon oxide layer on the entire surface of the first principal surface 201 of the p-type silicon wafer 20 by, for example, thermal oxidation; and forming a silicon nitride layer on the silicon oxide layer by, for example, chemical vapor deposition (CVD). The second processing includes patterning a layered structure of the silicon oxide layer and the silicon nitride layer into the prescribed pattern by using a photolithographic technique and an etching technique, thereby forming the insulating layer 6. Here, the first principal surface 201 of the p-type silicon wafer 20 corresponds to the first principal surface 21 of the silicon substrate 2. The insulating layer 6 having the prescribed pattern covers a region of the first principal surface 201 of the p-type silicon wafer 20 corresponding to the second region A2 of the first principal surface 21 of the silicon substrate 2 but does not cover a region of the first principal surface 201 of the p-type silicon wafer 20 corresponding to the first region A1 of the first principal surface 21 of the silicon substrate 2.

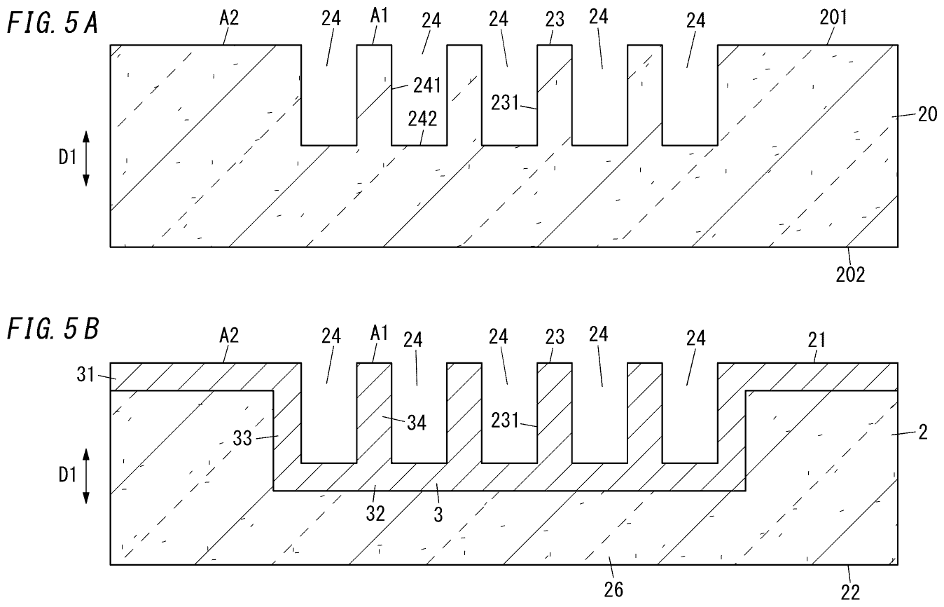

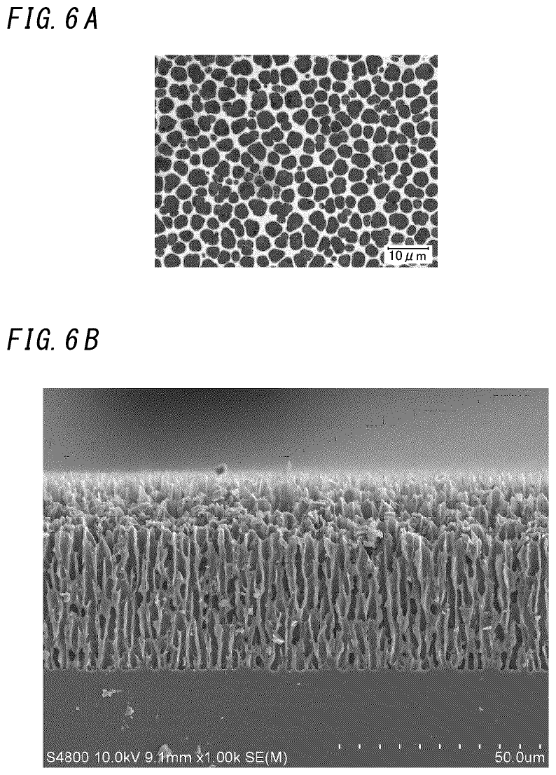

The third step includes anodizing the p-type silicon wafer 20 by using the p-type silicon wafer 20 as an anode, thereby forming the p-type silicon wafer 20 (see FIGS. 5A, 6A, and 6B) having the porous part 23, and then, removing the insulating layer 6. FIG. 6A is an example of a surface SEM image of the p-type silicon wafer 20 having the porous part 23. FIG. 6B is an example of a cross-sectional SEM image of the p-type silicon wafer 20 having the porous part 23. In the anodization, a platinum electrode is disposed to face the first principal surface 201 of the p-type silicon wafer 20 in an electrolytic solution, and a current having a prescribed current density is allowed to flow for a predetermined time period while the p-type silicon wafer 20 is used as an anode and the platinum electrode is used as a cathode. Thus, in the anodization, the p-type silicon wafer 20 is made porous in a region which is part of the first principal surface 201 of the p-type silicon wafer 20 and which is not covered with the insulating layer 6. The electrolytic solution is, for example, a mixed liquid of hydrofluoric acid and ethanol. Note that before the anodization, an electrode which is to be used in the anodization is formed on the second principal surface 202 of the p-type silicon wafer 20. This electrode is removed after the anodization. The electrode is, for example, a metal film.

In the third step, changing at least one of the concentration of hydrogen fluoride in the electrolytic solution, the prescribed current density, or the predetermined time period enables the shapes and the depths of the plurality of micropores 24 to be controlled. The concentration of hydrogen fluoride in the electrolytic solution is, for example, higher than or equal to 1 wt % and lower than or equal to 80 wt %, more preferably higher than or equal to 20 wt % and lower than or equal to 40 wt %. Moreover, in the method of manufacturing the capacitor 1, the shapes of the plurality of micropores 24 can be changed by changing the specific resistance of the p-type silicon wafer 20 determined by the impurity concentration of the p-type silicon wafer 20 from which the silicon substrate 2 is to be formed.

The fourth step includes forming the doped layer 3 from the diffusion layer in the p-type silicon wafer 20 as shown in FIG. 5B. That is, the fourth step includes a diffusion step. The diffusion step includes heat-diffusing a p-type dopant (e.g., boron) into the p-type silicon wafer 20, thereby forming the doped layer 3. Thus, the silicon substrate 2 having the porous part 23 and the doped layer 3 is formed.

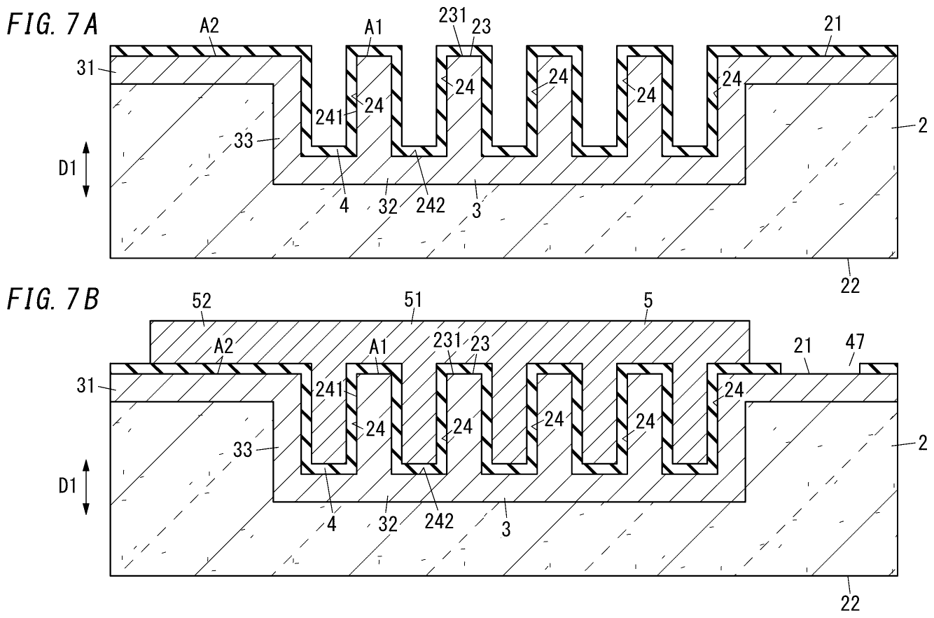

The fifth step includes forming the dielectric layer 4 on the doped layer 3 as shown in FIG. 7A. In the fifth step, a first silicon oxide film of the dielectric layer 4 is formed by, for example, CVD, a silicon nitride film of the dielectric layer 4 is formed by, for example, CVD, and a second silicon oxide film of the dielectric layer 4 is formed by, for example, CVD. Note that the first silicon oxide film may be formed by thermal oxidation.

The sixth step includes forming the conductor layer 5 on the dielectric layer 4 as shown in FIG. 7B. More specifically, the sixth step includes forming, first of all, on the dielectric layer 4, a conductor material layer from which the conductor layer 5 is to be formed. In the sixth step, the conductor material layer is formed by, for example, CVD, and thereafter, the conductor material layer is patterned by using, for example, a photolithographic technique and an etching technique, thereby forming the conductor layer 5 from part of the conductor material layer. The conductor layer 5 has a first portion 51 overlapping the first region A1 and a second portion 52 overlapping the second region A2 in the thickness direction D1 defined with respect to the silicon substrate 2.

The seventh step includes forming the first external connection electrode 7 and the second external connection electrode 8 (see FIG. 1). More specifically, the seventh step includes forming, first of all, the contact hole 47 (see FIG. 7B) in the dielectric layer 4, thereby exposing part of the first principal surface 21 of the silicon substrate 2. In the seventh step, the contact hole 47 is formed by using, for example, a photolithographic technique and an etching technique. Then, for example, a thin film forming method, a photolithographic technique, and an etching technique are used, thereby forming the first external connection electrode 7 and the second external connection electrode 8. The thin film forming method is, for example, evaporation, sputtering, or CVD. The seventh step may include heat treatment for achieving an ohmic contact between the first external connection electrode 7 and the doped layer 3.

In the method of manufacturing the capacitor 1, a first wafer (e.g., a silicon wafer) may be prepared as the p-type silicon wafer 20 in the first step, and then, the first step to seventh steps may be performed, thereby obtaining a second wafer including a plurality of capacitors 1. In the method of manufacturing the capacitor 1, the second wafer may be cut in the eighth step by using, for example, a dicing saw or a laser dicing device, thereby obtaining a plurality of capacitors 1.

### (3) Advantages

In the capacitor 1 according to the first embodiment, the dielectric layer 4 is disposed over the surface 231 of the porous part 23 and the second region A2 of the silicon substrate 2. Moreover, the conductor layer 5 disposed on the dielectric layer 4 overlaps the first region A1 and part of the second region A2 in plan view in the thickness direction D1 defined with respect to the silicon substrate 2. Moreover, the silicon substrate 2 has the doped layer 3, and the doped layer 3 includes the first doped layer 31 formed along the second region A2 of the silicon substrate 2, the second doped layer 32 formed at the bottom part of the porous part 23 of the silicon substrate 2, and the third doped layer 33 formed at the side part of the porous part 23 of the silicon substrate 2. This allows the capacitor 1 according to the first embodiment to have improved electrical characteristics. More specifically, the capacitor 1 according to the first embodiment is allowed to have further increased capacitance.

Moreover, the capacitor 1 according to the first embodiment includes, in the doped layer 3: the first portion 35 connecting the first doped layer 31 to the third doped layer 33 and having the first curved part 351 concavely curved in the cross-sectional view in the second direction D2 orthogonal to the first direction D1 which is the thickness direction D1; and the second portion 36 connecting the second doped layer 32 to the third doped layer 33 and having the second curved part 361 convexly curved in the cross-sectional view. Thus, the capacitor 1 according to the first embodiment has suppressed electric field concentration at each of the first portion 35 and the second portion 36 and thus has reduced equivalent series resistance (ESR). Further, the capacitor 1 according to the first embodiment allows reflection of a current at the second portion 36 to be reduced, thereby reducing transmission loss.

Moreover, in the capacitor 1 according to the first embodiment, the silicon substrate 2 has the doped layer 3, and thus, there is the advantage that the surface 231 of the porous part 23 readily has an increased surface area. More specifically, the porous part 23 is formed by anodizing the p-type silicon wafer 20 having a lower impurity concentration than the doped layer 3 before forming the doped layer 3, thereby increasing the surface area of the surface 231 of the porous part 23.

### (4) Variations of First Embodiment

The conductivity types of the body region 26 and the doped layer 3 of the silicon substrate 2 are not limited to p-type but may be n-type. When the conductivity types of the body region 26 and the doped layer 3 of the silicon substrate 2 are n-type, the body region 26 and the doped layer 3 contain, for example, phosphorus (P) as an n-type dopant, but this should not be construed as limiting. The body region 26 and the doped layer 3 may contain arsenic (As) or antimony (Sb) as the dopant. Moreover, also when the conductivity types of the body region 26 and the doped layer 3 of the silicon substrate 2 are n-type, the impurity concentration of the doped layer 3 is higher than the impurity concentration of the body region 26. Moreover, the carrier concentration of the doped layer 3 is higher than the carrier concentration of the body region 26.

When the conductivity types of the doped layer 3 and the body region 26 are n-type, the method of manufacturing the capacitor 1 is substantially the same as the method of manufacturing the capacitor 1 according to the first embodiment. Note that in the first step, an n-type silicon substrate is prepared as an alternative to the p-type silicon wafer 20. Moreover, to form the porous part 23 by the anodization, the n-type silicon substrate from which be the silicon substrate 2 is to be formed is irradiated with light to increase the number of holes in the n-type silicon substrate.

### Second Embodiment

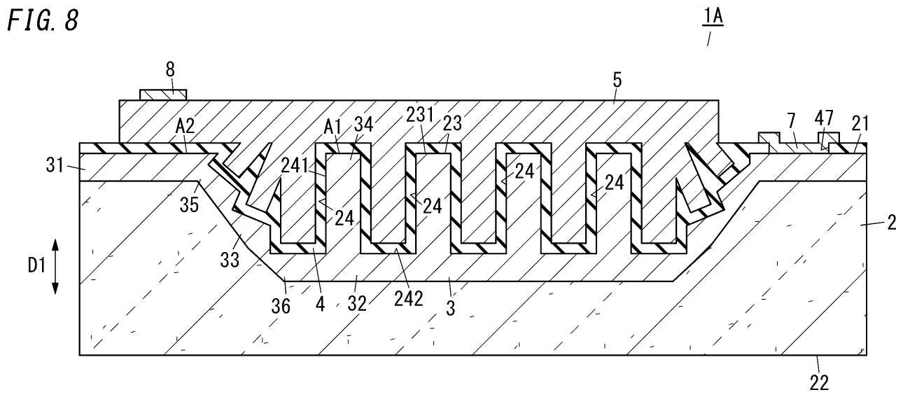

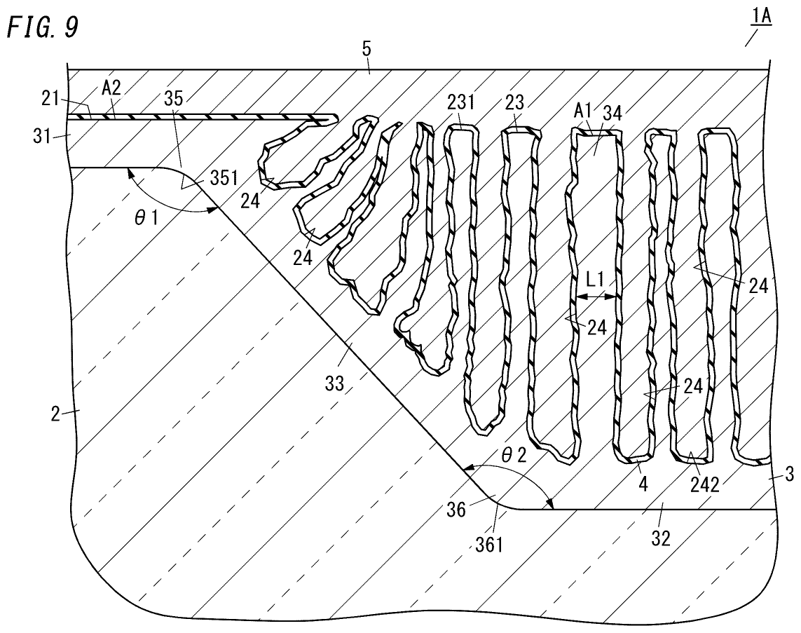

With reference to FIGS. 8 and 9, a capacitor 1A according to a second embodiment will be described below. In the capacitor 1A according to the second embodiment, components similar to those in the capacitor 1 according to the first embodiment (see FIGS. 1 to 3) are denoted by the same reference signs as those in the first embodiment, and the description thereof is accordingly omitted.

### (1) Configuration

The capacitor 1A according to the second embodiment includes a silicon substrate 2, a dielectric layer 4, and a conductor layer 5. The silicon substrate 2 has a first principal surface 21 and a second principal surface 22. The silicon substrate 2 has a porous part 23 having a plurality of micropores 24 formed in the first principal surface 21. Moreover, the silicon substrate 2 has a doped layer 3 containing a p-type dopant (e.g., boron or indium). The doped layer 3 is disposed along a surface 231 of the porous part 23. The dielectric layer 4 has a shape conforming to the shape of the surface 231 of the porous part 23 and is disposed on the doped layer 3. The conductor layer 5 is disposed on the dielectric layer 4.

In the capacitor 1A, the doped layer 3 constitutes a first electrode of the capacitor 1A, and the conductor layer 5 constitutes a second electrode of the capacitor 1A. Thus, in the capacitor 1A, the dielectric layer 4 is located between the first electrode and the second electrode.

Moreover, the capacitor 1A further includes a first external connection electrode 7 and a second external connection electrode 8. The first external connection electrode 7 is connected to the doped layer 3. The second external connection electrode 8 is connected to the conductor layer 5.

The doped layer 3 includes a first doped layer 31, a second doped layer 32, and a third doped layer 33. The first doped layer 31 is disposed along a second region A2 of the silicon substrate 2. The second doped layer 32 is disposed at a bottom part of the porous part 23 of the silicon substrate 2. The third doped layer 33 is disposed at a side part of the porous part 23 of the silicon substrate 2. In the doped layer 3, the first doped layer 31 is connected to the third doped layer 33. Moreover, in the doped layer 3, the second doped layer 32 is connected to the third doped layer 33.

In the capacitor 1A according to the second embodiment, shapes of the porous part 23 and the doped layer 3 in a cross-sectional view in the second direction D2 (see FIG. 3) are different from the shapes of the porous part 23 and the doped layer 3 of the capacitor 1 according to the first embodiment, respectively.

In the capacitor 1A, the porous part 23 has an inverted trapezoidal shape in the cross-sectional view in the second direction D2, and the porous part 23 has a decreasing width away from the first principal surface 21. The porous part 23 in the capacitor 1A includes: a first porous region having a first group of micropores 24 which are included in the plurality of micropores 24 and which are formed from the first principal surface 21 of the silicon substrate 2 in a thickness direction D1; and a second porous region having a second group of micropores 24 which are included in the plurality of micropores 24 and which are formed from the first principal surface 21 of the silicon substrate 2 in an oblique direction.

In the doped layer 3 of the capacitor 1A, the first doped layer 31 is connected to the third doped layer 33, and in the cross-sectional view in the second direction D2 orthogonal to a first direction D1 which is the thickness direction D1, a smaller angle θ1 of two angles formed between the first doped layer 31 and the third doped layer 33 is an obtuse angle. In the doped layer 3, the second doped layer 32 is connected to the third doped layer 33, and in the cross-sectional view, a smaller angle θ2 of two angles formed between the second doped layer 32 and the third doped layer 33 is an obtuse angle.

The doped layer 3 has a first portion 35 connecting the first doped layer 31 to the third doped layer 33. The first portion 35 has a first curved part 351 concavely curved (arc-shaped) in the cross-sectional view in the second direction D2. The doped layer 3 has a second portion 36 connecting the second doped layer 32 to the third doped layer 33. The second portion 36 has a second curved part 361 convexly curved (arc-shaped) in the cross-sectional view.

In the doped layer 3, the first curved part 351 has a curvature radius greater than or equal to 10 nm and less than or equal to 10 μm. Moreover, the second curved part 361 has a curvature radius greater than or equal to 10 nm and less than or equal to 10 μm.

Moreover, the doped layer 3 further includes a fourth doped layer 34. The fourth doped layer 34 is disposed at a portion between two adjacent micropores 24 of the plurality of micropores 24 in the porous part 23 of the silicon substrate 2.

### (2) Manufacturing Method

A method of manufacturing the capacitor 1A according to the second embodiment is substantially the same as the method of manufacturing the capacitor 1 according to the first embodiment. The description of steps in the method of manufacturing the capacitor 1A according to the second embodiment which are similar to those in the method of manufacturing the capacitor 1 according to the first embodiment will accordingly be omitted.

The method of manufacturing the capacitor 1A according to the second embodiment includes a first step, a second step, a third step, a fourth step, a fifth step, a sixth step, a seventh step, and an eighth step in a similar manner to the method of manufacturing the capacitor 1 according to the first embodiment.

In the method of manufacturing the capacitor 1A according to the second embodiment, the shape of the porous part 23 formed in the third step is different from that in the first embodiment. The shape of the porous part 23 can be controlled by changing at least one of the condition of anodization and the impurity concentration of the p-type silicon wafer 20 (see FIG. 4A) from which the silicon substrate 2 is to be formed.

### (3) Advantages

In the capacitor 1A according to the second embodiment, the dielectric layer 4 is disposed over the surface 231 of the porous part 23 and the second region A2 of the silicon substrate 2. Moreover, the conductor layer 5 formed on the dielectric layer 4 overlaps a first region A1 and part of the second region A2 in plan view in the thickness direction D1 defined with respect to the silicon substrate 2. Moreover, the silicon substrate 2 has the doped layer 3, and the doped layer 3 includes the first doped layer 31 formed along the second region A2 of the silicon substrate 2, the second doped layer 32 formed at the bottom part of the porous part 23 of the silicon substrate 2, and the third doped layer 33 formed at the side part of the porous part 23 of the silicon substrate 2. This allows the capacitor 1A according to the second embodiment to have improved electrical characteristics. More specifically, the capacitor 1A according to the second embodiment is allowed to have further increased capacitance.

Moreover, in the doped layer 3 of the capacitor 1A according to the second embodiment, the first doped layer 31 is connected to the third doped layer 33, and in the cross-sectional view in the second direction D2 orthogonal to the first direction D1 which is the thickness direction D1, the smaller angle θ1 of the two angles formed between the first doped layer 31 and the third doped layer 33 is an obtuse angle. In the doped layer 3, the second doped layer 32 is connected to the third doped layer 33, and in the cross-sectional view, the smaller angle θ2 of the two angles formed between the second doped layer 32 and the third doped layer 33 is an obtuse angle. Thus, the capacitor 1A according to the second embodiment has reduced ESR and reduced transmission loss as compared with the case where the angle θ1 and the angle θ2 are each 90 degrees.

Moreover, the capacitor 1A according to the second embodiment includes, in the doped layer 3, the first portion 35 connecting the first doped layer 31 to the third doped layer 33 and having the first curved part 351 concavely curved in a cross-sectional view in the second direction D2, and the second portion 36 connecting the second doped layer 32 to the third doped layer 33 and having the second curved part 361 convexly curved in the cross-sectional view. Thus, the capacitor 1A according to the second embodiment has suppressed electric field concentration at each of the first portion 35 and the second portion 36 and thus has reduced ESR.

### Variation of Second Embodiment

The conductivity types of a body region 26 and the doped layer 3 of the silicon substrate 2 are not limited to p-type but may be n-type. When the conductivity types of the body region 26 and the doped layer 3 of the silicon substrate 2 are n-type, the body region 26 and the doped layer 3 contain, for example, phosphorus as an n-type dopant, but this should not be construed as limiting. The body region 26 and the doped layer 3 may contain arsenic or antimony as the n-type dopant. Moreover, also when the conductivity types of the body region 26 and the doped layer 3 of the silicon substrate 2 are n-type, the impurity concentration of the doped layer 3 is higher than the impurity concentration of the body region 26. Moreover, the carrier concentration of the doped layer 3 is higher than the carrier concentration of the body region 26.

When the conductivity types of the doped layer 3 and the body region 26 are n-type, the method of manufacturing the capacitor 1A is substantially the same as the method of manufacturing the capacitor 1A according to the second embodiment. Note that in the first step, an n-type silicon substrate is prepared as an alternative to the p-type silicon wafer 20. Moreover, to form the porous part 23 by the anodization, the n-type silicon substrate from which the silicon substrate 2 is to be formed is irradiated with light to increase the number of holes in the n-type silicon substrate.

### Other Variations

The first and second embodiments, and the like are mere examples of various embodiments of the present disclosure. Various modifications may be made to the first and second embodiments, and the like depending on the design or the like as long as the object of the present disclosure is achieved.

For example, the silicon substrate 2 may be provided with a plurality of circuit elements (e.g., MOSFET) other than the capacitor 1, 1A. That is, the capacitor 1, 1A according to the present disclosure is appliable to a semiconductor device including the capacitor 1, 1A, for example, an integrated circuit (IC) chips including the capacitor 1, 1A.

### Aspects

The present specification discloses the following aspects from the first and second examples and the like.

A capacitor (1; 1A) of a first aspect includes a silicon substrate (2), a dielectric layer (4), and a conductor layer (5). The silicon substrate (2) has a first principal surface (21) including a first region (A1) and a second region (A2) surrounding the first region (A1), a second principal surface (22), and a porous part (23) formed in the first region (A1) and having a plurality of micropores (24) along a thickness direction (D1) defined with respect to the silicon substrate (2). The dielectric layer (4) is disposed over a surface (231) of the porous part (23) and the second region (A2) of the silicon substrate (2). The conductor layer (5) is disposed on the dielectric layer (4). An interval (L1) between two adjacent micropores (24) of the plurality of micropores (24) is ununiform in the thickness direction (D1) defined with respect to the silicon substrate (2). The conductor layer (5) overlaps the first region (A1) and the second region (A2) in plan view in the thickness direction (D1) defined with respect to the silicon substrate (2). The silicon substrate (2) has a doped layer (3). The doped layer (3) includes a first doped layer (31), a second doped layer (32), and a third doped layer (33). The first doped layer (31) is disposed along the second region (A2) of the silicon substrate (2). The second doped layer (32) is disposed at a bottom part of the porous part (23) of the silicon substrate (2). The third doped layer (33) is disposed at a side part of the porous part (23) of the silicon substrate (2). The doped layer (3) has a first portion (35) connecting the first doped layer (31) to the third doped layer (33). The first portion (35) has a first curved part (351) concavely curved in a cross-sectional view in a second direction (D2) orthogonal to a first direction (D1) which is the thickness direction (D1). The doped layer (3) includes a second portion (36) connecting the second doped layer (32) to the third doped layer (33). The second portion (36) has a second curved part (361) convexly curved in the cross-sectional view.

This aspect allows an improvement in electrical characteristics.

In a capacitor (1; 1A) of a second aspect referring to the first aspect, in the cross-sectional view, a smaller angle (θ1) of two angles formed between the first doped layer (31) and the third doped layer (33) is an obtuse angle, and a smaller angle (θ2) of two angles formed between the second doped layer (32) and the third doped layer (33) is an obtuse angle.

This aspect enables the ESR and the transmission loss to be reduced.

A capacitor (1A) of a third aspect includes a silicon substrate (2), a dielectric layer (4), and a conductor layer (5). The silicon substrate (2) has a first principal surface (21) including a first region (A1) and a second region (A2) surrounding the first region (A1), a second principal surface (22), and a porous part (23) formed in the first region (A1) and having a plurality of micropores (24) along a thickness direction (D1) defined with respect to the silicon substrate (2). The dielectric layer (4) is disposed over a surface (231) of the porous part (23) and the second region (A2) of the silicon substrate (2). The conductor layer (5) is disposed on the dielectric layer (4). An interval (L1) between two adjacent micropores (24) of the plurality of micropores (24) is ununiform in the thickness direction (D1) defined with respect to the silicon substrate (2). The conductor layer (5) overlaps the first region (A1) and part of the second region (A2) in plan view in the thickness direction (D1) defined with respect to the silicon substrate (2). The silicon substrate (2) has a doped layer (3). The doped layer (3) includes a first doped layer (31), a second doped layer (32), and a third doped layer (33). The first doped layer (31) is disposed along the second region (A2) of the silicon substrate (2). The second doped layer (32) is disposed at a bottom part of the porous part (23) of the silicon substrate (2). The third doped layer (33) is disposed at a side part of the porous part (23) of the silicon substrate (2). In the doped layer (3), the first doped layer (31) is connected to the third doped layer (33), and a smaller angle (θ1) of two angles formed between the first doped layer (31) and the third doped layer (33) is an obtuse angle in a cross-sectional view in a second direction (D2) orthogonal to a first direction (D1) which is the thickness direction (D1). In the doped layer (3), the second doped layer (32) is connected to the third doped layer (33), and a smaller angle (θ2) of two angles formed between the second doped layer (32) and the third doped layer (33) is an obtuse angle in the cross-sectional view.

This aspect allows an improvement in electrical characteristics.

In a capacitor (1; 1A) of a fourth aspect referring to the first or second aspect, the first curved part (351) has a curvature radius greater than or equal to 10 nm and less than or equal to 10 μm, and the second curved part (361) has a curvature radius greater than or equal to 10 nm and less than or equal to 10 μm.

This aspect allows electric field concentration at each of the first portion (35) and the second portion (36) of the doped layer (3) to be suppressed.

In a capacitor (1; 1A) of a fifth aspect referring to any one of the first to fourth aspects, the plurality of micropores (24) in the porous part (23) each have an inner bottom surface (242) which is concavely curved.

This aspect allows electric field concentration at the doped layer (3) to be suppressed.

In a capacitor (1; 1A) of a sixth aspect referring to the fifth aspect, the inner bottom surface (242) of each of the plurality of micropores (24) has a curvature radius greater than or equal to 1.25 nm.

In a capacitor (1; 1A) of a seventh aspect referring to any one of the first to sixth aspects, the doped layer (3) further includes a fourth doped layer (34) between two adjacent micropores (24) of the plurality of micropores (24) in the porous part (23) of the silicon substrate (2).

This aspect enables ESR to be reduced.

In a capacitor (1; 1A) of an eighth aspect referring to any one of the first to seventh aspects, when the doped layer (3) contains a p-type dopant, the p-type dopant is boron or indium, and when the doped layer (3) contains an n-type dopant, the n-type dopant is phosphorus, arsenic, or antimony.

### Reference Signs List

1, 1A Capacitor
2 Silicon Substrate
21 First Principal Surface
22 Second Principal Surface
23 Porous Part
231 Surface
24 Micropore
241 Inner Side Surface
242 Inner Bottom Surface
3 Doped Layer
31 First Doped Layer
32 Second Doped Layer
33 Third Doped Layer
34 Fourth Doped Layer
35 First Portion
351 First Curved Part
36 Second Portion
361 Second Curved Part
4 Dielectric Layer
5 Conductor Layer
7 First External Connection Electrode
8 Second External Connection Electrode
A1 First Region
A2 Second Region
D1 Thickness Direction (First Direction)
D2 Second Direction
T1 Thickness
T2 Thickness
T3 Thickness
L1 Interval
θ1 Angle
θ2 Angle

1. A capacitor comprising:
a silicon substrate having
a first principal surface including a first region and a second region surrounding the first region,
a second principal surface, and
a porous part formed in the first region and having a plurality of micropores along a thickness direction defined with respect to the silicon substrate;
a dielectric layer disposed over a surface of the porous part and the second region of the silicon substrate; and
a conductor layer disposed on the dielectric layer,
an interval between adjacent micropores of the plurality of micropores being ununiform in the thickness direction defined with respect to the silicon substrate,
the conductor layer overlapping the first region and the second region in plan view in the thickness direction defined with respect to the silicon substrate,
the silicon substrate having a doped layer containing a p-type dopant or an n-type dopant,
the doped layer including
a first doped layer disposed along the second region of the silicon substrate,
a second doped layer disposed at a bottom part of the porous part of the silicon substrate, and
a third doped layer disposed at a side part of the porous part of the silicon substrate,
the doped layer having
a first portion connecting the first doped layer to the third doped layer, the first portion having a first curved part concavely curved in a cross-sectional view in a second direction orthogonal to a first direction which is the thickness direction, and
a second portion connecting the second doped layer to the third doped layer, the second portion having a second curved part convexly curved in the cross-sectional view.

2. The capacitor of claim 1, wherein
in the cross-sectional view in the second direction, a smaller angle of two angles formed between the first doped layer and the third doped layer is an obtuse angle, and
in the cross-sectional view, a smaller angle of two angles formed between the second doped layer and the third doped layer is an obtuse angle.

3. A capacitor comprising:
a silicon substrate having
a first principal surface including a first region and a second region surrounding the first region,
a second principal surface, and
a porous part formed in the first region and having a plurality of micropores along a thickness direction defined with respect to the silicon substrate;
a dielectric layer disposed over a surface of the porous part and the second region of the silicon substrate;
a conductor layer disposed on the dielectric layer, and
an interval between adjacent micropores of the plurality of micropores being ununiform in the thickness direction defined with respect to the silicon substrate,
the conductor layer overlapping the first region and the second region in plan view in the thickness direction defined with respect to the silicon substrate,
the silicon substrate having a doped layer containing a p-type dopant or an n-type dopant,
the doped layer including
a first doped layer disposed along the second region of the silicon substrate,
a second doped layer disposed at a bottom part of the porous part of the silicon substrate, and
a third doped layer disposed at a side part of the porous part of the silicon substrate,
in the doped layer,
the first doped layer being connected to the third doped layer, a smaller angle of two angles formed between the first doped layer and the third doped layer being an obtuse angle in a cross-sectional view in a second direction orthogonal to a first direction which is the thickness direction, and
the second doped layer being connected to the third doped layer, a smaller angle of two angles formed between the second doped layer and the third doped layer being an obtuse angle in the cross-sectional view.

4. The capacitor of claim 1, wherein
the first curved part has a curvature radius greater than or equal to 10 nm and less than or equal to 10 μm, and
the second curved part has a curvature radius greater than or equal to 10 nm and less than or equal to 10 μm.

5. The capacitor of claim 1, wherein
the plurality of micropores in the porous part each have an inner bottom surface which is concavely curved.

6. The capacitor of claim 5, wherein
the inner bottom surface of each of the plurality of micropores has a curvature radius greater than or equal to 1.25 nm.

7. The capacitor of claim 1, wherein
the doped layer further includes a fourth doped layer between two adjacent micropores of the plurality of micropores in the porous part of the silicon substrate.

8. The capacitor of claim 1, wherein
when the doped layer contains the p-type dopant, the p-type dopant is boron or indium, and
when the doped layer contains the n-type dopant, the n-type dopant is phosphorus, arsenic, or antimony.
